(19) United States
(12) Patent Application Publication
(10) Pub. No.: US 2025/0379045 A1
(43) Pub. Date: Dec. 11, 2025

(54) WAFER CLEANING METHOD AND SYSTEM

(71) Applicant: Tokyo Electron Limited, Tokyo (JP)

(72) Inventors: Ronald NASMAN, Albany, NY (US); Peter DELIA, Albany, NY (US); Derek BASSETT, Austin, TX (US)

(73) Assignee: Tokyo Electron Limited, Tokyo (JP)

(21) Appl. No.: 18/734,581

(22) Filed: Jun. 5, 2024

(51) Int. Cl. H01L 21/02; B01D 3/14; H01L 21/67

(52) U.S. Cl. CPC H01L 21/02057; B01D 3/143; H01L 21/67051; H01L 21/67098

(57) ABSTRACT

A wafer processing method and system are provided. The wafer processing system includes an isopropyl alcohol (IPA) evaporation system and a process chamber. The IPA evaporation system evaporates liquid IPA into IPA vapor. The IPA vapor is injected into the process chamber of the wafer processing system and condensed into distilled high purity liquid IPA. The distilled high purity liquid IPA is used to rinse a top surface of a semiconductor wafer in the process chamber.

### TECHNICAL FIELD

This disclosure relates generally to the processing and surface preparation of semiconductor wafers, and particularly to a method and wafer processing system for cleaning of such wafers.

### BACKGROUND

Semiconductor fabrication involves many different steps of depositing, growing, patterning, removal, and cleaning of wafers. The cleaning of the wafers can be referred to as wafer cleaning process, which includes rinsing the wafers using deionized water, displacing the deionized water with isopropyl alcohol (IPA) liquid to reduce the risks of pattern collapses on the wafers, and drying the wafers. However, the use of the IPA liquid can introduce significant particle contamination onto the wafers. Accordingly, there is a demanding need to reduce the particle contamination during the IPA supply.

### SUMMARY

This disclosure provides a wafer cleaning method. In the wafer cleaning method, liquid isopropyl alcohol (IPA) is evaporated into IPA vapor by an IPA evaporation system of a wafer processing system. The IPA vapor is injected into a process chamber of the wafer processing system and condensed into distilled high purity liquid IPA. The distilled high purity liquid IPA is used to rinse a top surface of a semiconductor in the process chamber.

Aspects of the disclosure provide a wafer processing system. The wafer processing system includes an IPA evaporation system and a process chamber. The IPA evaporation system evaporates liquid IPA into IPA vapor. The IPA vapor is injected into the process chamber of the wafer processing system and condensed into distilled high purity liquid IPA. The distilled high purity liquid IPA is used to rinse a top surface of a semiconductor in the process chamber.

### BRIEF DESCRIPTION OF DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 illustrates a schematic of a wafer processing system according to an embodiment of the disclosure.

FIGS. 2A-2B show two examples of dispensing liquid isopropyl alcohol (IPA) vapor into a process chamber according to embodiments of the disclosure.

FIGS. 3A-3B show two examples of dispensing the IPA vapor by cooling the semiconductor wafer according to embodiments of the disclosure.

FIGS. 4A-4D show four examples of dispensing the IPA vapor by heating the process chamber or generating a gas curtain flow according to embodiments of the disclosure.

FIG. 5 illustrates a flowchart outlining a wafer cleaning process according to an embodiment of the disclosure.

### DETAILED DESCRIPTION

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

In semiconductor device manufacturing, a wafer cleaning process can involve rinsing a wafer surface of a semiconductor wafer using deionized water (DIW), displacing the DIW using isopropyl alcohol (IPA) to prevent pattern collapses on the semiconductor wafer, and then drying the wafer surface using a clean gas such as nitride gas. In some related arts, liquid IPA is used in the wafer cleaning process. However, since the liquid IPA is the last liquid used in the process, mechanical pumps and valves in the IPA delivery can introduce significant particle contamination into the process. Accordingly, there is a need to remove the source of the contamination and provide clean IPA in the wafer cleaning process.

Aspects of the disclosure provide wafer cleaning methods and systems of providing distilled high purity liquid IPA.

According to aspects of the disclosure, a wafer cleaning process can include evaporating liquid IPA into IPA vapor, injecting the IPA vapor into a process chamber, condensing the IPA vapor into distilled high purity liquid IPA, and rinsing a semiconductor wafer in the process chamber using the distilled high purity liquid IPA. The use of the distilled high purity liquid IPA in the wafer cleaning process can reduce the risks of particle contamination.

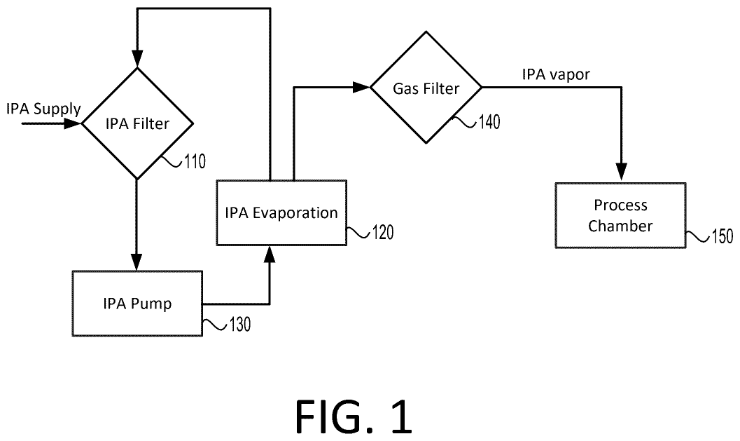

FIG. 1 illustrates a schematic of a wafer processing system 100 according to an embodiment of the disclosure. In the wafer processing system 100, liquid IPA can be first supplied into an IPA filter 110, which can filter out at least a part of particles contained in the liquid IPA. The filtered liquid IPA can be then pumped into an IPA evaporation system 120 through an IPA pump 130. In the IPA evaporation system 120, the filtered liquid IPA can be evaporated into IPA vapor. The IPA vapor can be fed into a gas filter 140, which can further filter out any particles contained in the IPA vapor. The filtered IPA vapor can be injected into a process chamber 150. In the process chamber 150, the filtered IPA vapor can be condensed into distilled high purity liquid IPA. The distilled high purity liquid IPA can be used to clean a semiconductor wafer in the process chamber 150.

In an embodiment, to reduce the particles left in the IPA evaporation system 120 after evaporating the filtered liquid IPA into the IPA vapor, the filtered liquid IPA left in the IPA evaporation system 120 can be further fed into the IPA filter 110.

In an embodiment, the filtered IPA vapor can be injected onto a top surface of the semiconductor wafer. A back surface of the semiconductor wafer can be cooled so that the filtered IPA vapor can be condensed on the top surface of the semiconductor wafer. In an example, the back surface of the semiconductor wafer can be cooled by dispensing a low temperature IPA liquid onto the back surface of the semiconductor wafer.

In an embodiment, rinsing the top surface of the semiconductor wafer using the DIW can continue while the IPA vapor is injected into the process chamber. A condensation rate of condensing the IPA vapor into the distilled high purity liquid IPA needs to be sufficient to continue to wet the top surface of the semiconductor wafer. A rotation of the semiconductor wafer may be slowed to allow the DIW on the top surface of the semiconductor wafer to fully transit to the distilled high purity liquid IPA via a concentration shift.

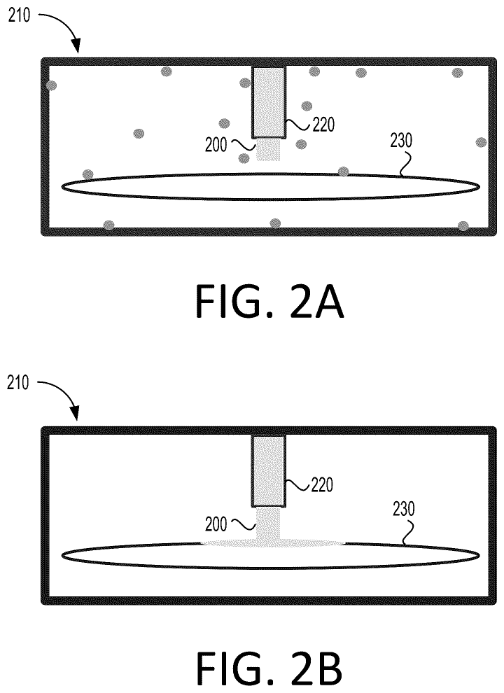

FIGS. 2A-2B show two examples of dispensing IPA vapor 200 into a process chamber 210 according to embodiments of the disclosure. The IPA vapor 200 can be dispensed through a nozzle 220 of the process chamber 210 onto a semiconductor wafer 230. In FIG. 2A, after being dispensed into the process chamber 210, the IPA vapor 200 can disperse all over the process chamber 210. This can lead to particle risks and cross contamination risks from wafer to wafer. Accordingly, it is desired to deposit the IPA vapor 200 primarily on a top surface of the semiconductor wafer 230, as shown in FIG. 2B According to embodiments of the disclosure, cooling the semiconductor wafer

230 can force the IPA vapor 200 to be deposited primarily on the top surface of the semiconductor wafer 230.

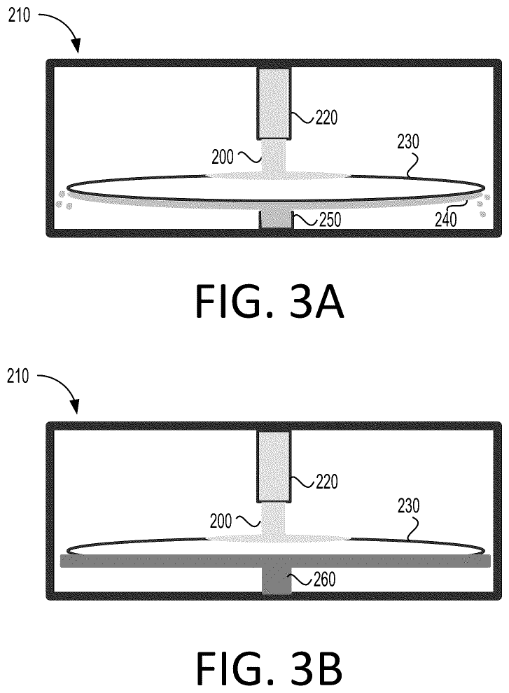

FIGS. 3A-3B show two examples of dispensing the IPA vapor 200 by cooling the semiconductor wafer 230 according to embodiments of the disclosure.

In FIG. 3A, a cold distilled IPA liquid 240 (e.g., at room temperature) can be dispensed through a nozzle 250 of the process chamber 210 onto a back surface of the semiconductor wafer 230. The cold distilled IPA liquid 240 can cool the semiconductor wafer 230 so that the IPA vapor 200 can be condensed primarily on the top surface of the semiconductor wafer 230. The cold distilled IPA liquid 240 can also allow to collect the condensed IPA and reuse it for a next cleaning process.

In an embodiment, the DIW can be dispensed through the nozzle 250 onto the back surface of the semiconductor wafer 230 to cool the semiconductor wafer 230.

In an embodiment, a cold gas such as a cold nitrogen gas can be dispensed through the nozzle 250 onto the back surface of the semiconductor wafer 230 to cool the semiconductor wafer 230.

In FIG. 3B, the semiconductor wafer 230 can be held on a cold chuck 260 so that the IPA vapor 200 can be condensed primarily on the top surface of the semiconductor wafer 230. The chuck 260 can be cooled with process cooling water (PCW), DIW, nitrogen gas, or the like.

According to embodiments of the disclosure, heating the process chamber 210 or generating a gas curtain flow for walls of the process chamber 210 can force the IPA vapor 200 to be deposited primarily on the top surface of the semiconductor wafer 230.

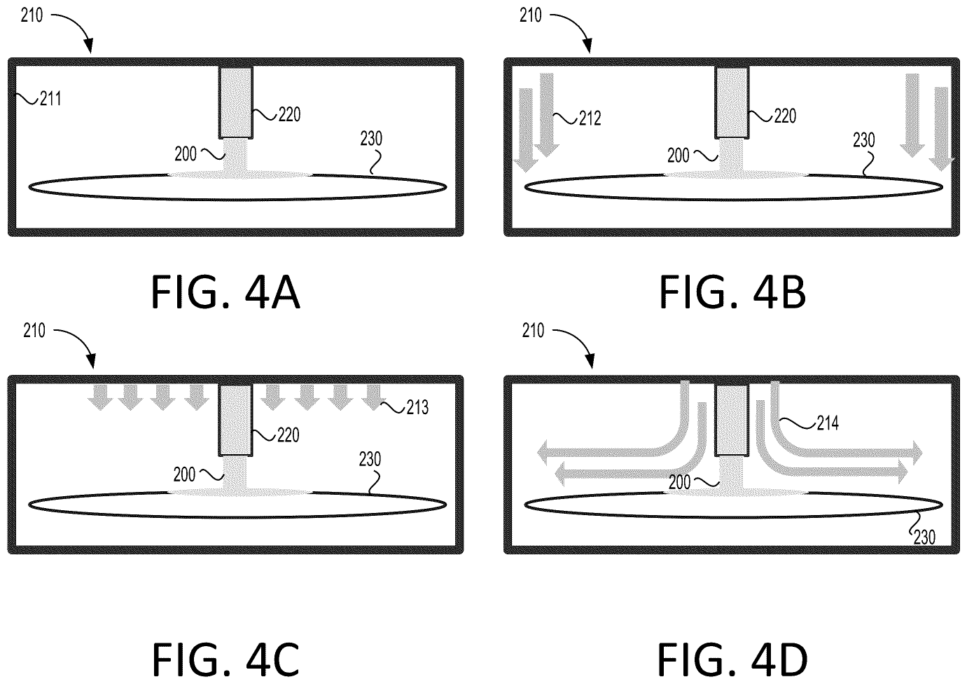

FIGS. 4A-4D show four examples of dispensing the IPA vapor 200 by heating the process chamber 210 or generating a gas curtain flow according to embodiments of the disclosure.

In FIG. 4A, walls 211 of the process chamber 210 can be heated to force the IPA vapor 200 to be deposited primarily on the top surface of the semiconductor wafer 230.

In FIG. 4B, a gas curtain flow 212 can be generated for the walls 211 of the process chamber 210 to force the IPA vapor 200 to be deposited primarily on the top surface of the semiconductor wafer 230. In an example, the gas curtain flow 212 can be a nitrogen gas or air. In an example, the gas curtain flow 212 can be heated or not heated.

In FIG. 4C, the process chamber 210 can be heated by a heated gas supply 213 to force the IPA vapor 200 to be deposited primarily on the top surface of the semiconductor wafer 230. In an example, the heated gas supply 213 can be a heated nitrogen gas or heated air.

In FIG. 4D, a heated laminar gas curtain flow 214 can be generated from the center of the process chamber 210 to the edge of the process chamber 210 to force the IPA vapor 200 to be deposited primarily on the top surface of the semiconductor wafer 230.

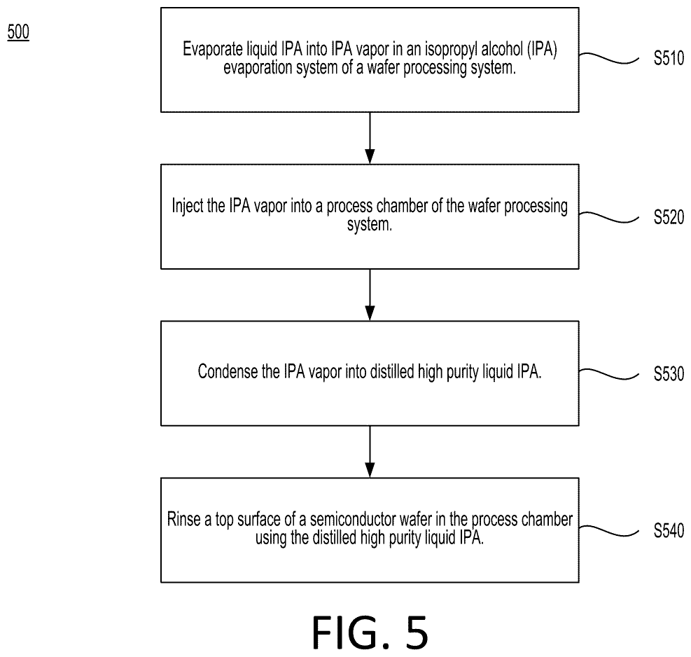

FIG. 5 illustrates a flowchart outlining a wafer cleaning process 500 for cleaning a semiconductor wafer according to embodiments of the disclosure. The wafer cleaning process 500 can be implemented by a wafer processing system (e.g., the wafer processing system 100). The wafer cleaning process 500 can be implemented as instructions stored in a non-transitory computer-readable medium. When executed by for example the wafer processing system, the instructions can cause the wafer processing system to perform the wafer cleaning process 500. The wafer cleaning process 500 may start at step S510.

At step S510, the process 500 can evaporate liquid IPA into IPA vapor in an IPA evaporation system of a wafer processing system. Then, the process 500 can proceed to step S520.

At step S520, the process 500 can inject the IPA vapor into a process chamber of the wafer processing system. Then, the process 500 can proceed to step S530.

At step S530, the process 500 can condense the IPA vapor into distilled high purity liquid IPA. Then, the process 500 can proceed to step S540.

At step S540, the process 500 can rinse a top surface of a semiconductor wafer in the process chamber using the distilled high purity liquid IPA.

In an embodiment, the process 500 can cool a back surface of the semiconductor wafer.

In an embodiment, the process 500 can rinse the top surface of the semiconductor wafer using deionized water while injecting the IPA vapor into the process chamber.

In an embodiment, the process 500 can displace the distilled high purity liquid IPA using a nitrogen gas to dry the semiconductor wafer.

In an embodiment, the process 500 can filter, by a gas filter of the wafer processing system, the IPA vapor before injecting the IPA vapor into the process chamber. In an embodiment, the process 500 can filter, by an IPA filter of the wafer

processing system, the liquid IPA that is left in the IPA evaporation system after evaporating the liquid IPA.

In an embodiment, the process 500 can pump, by an IPA pump of the wafer processing system, the filtered liquid IPA into the IPA evaporation system.

In an embodiment, the process 500 can heat walls of the process chamber while injecting the IPA vapor into the process chamber.

In an embodiment, the process 500 can generate a gas curtain flow for walls of the process chamber while injecting the IPA vapor into the process chamber.

In an embodiment, the process 500 can inject a heated gas supply into the process chamber to heat the process chamber while injecting the IPA vapor into the process chamber.

Aspects of the disclosure provide a wafer processing system. The wafer processing system includes an IPA evaporation system and a process chamber. The IPA evaporation system evaporates liquid IPA into IPA vapor. The IPA vapor is injected into the process chamber of the wafer processing system and condensed into distilled high purity liquid IPA. The distilled high purity liquid IPA is used to rinse a top surface of a semiconductor in the process chamber.

In an embodiment, the process chamber is configured to cool a back surface of the semiconductor wafer.

In an embodiment, the process chamber is configured to rinse the top surface of the semiconductor wafer using deionized water while injecting the IPA vapor into the process chamber.

In an embodiment, the process chamber is configured to displace the distilled high purity liquid IPA using a nitrogen gas to dry the semiconductor wafer.

In an embodiment, the wafer processing system includes a gas filter configured to filter the IPA vapor before the IPA vapor is injected into the process chamber.

In an embodiment, the wafer processing system includes an IPA filter configured to filter the liquid IPA that is left in the IPA evaporation system after the liquid IPA is evaporated into the IPA vapor.

In an embodiment, the wafer processing system includes an IPA pump configured to pump the filtered liquid IPA into the IPA evaporation system.

In an embodiment, the process chamber is configured to heat walls of the process chamber while injecting the IPA vapor into the process chamber.

In an embodiment, the process chamber is configured to generate a gas curtain flow for walls of the process chamber while injecting the IPA vapor into the process chamber.

In an embodiment, the process chamber is configured to inject a heated gas supply into the process chamber to heat the process chamber while injecting the IPA vapor into the process chamber.

Further modifications and alternative embodiments of the inventions will be apparent to those skilled in the art in view of this description. Accordingly, this description is to be construed as illustrative only and is for the purpose of teaching those skilled in the art the manner of carrying out the inventions. It is to be understood that the forms and method of the inventions herein shown and described are to be taken as presently preferred embodiments. Equivalent techniques may be substituted for those illustrated and described herein and certain features of the inventions may be utilized independently of the use of other features, all as would be apparent to one skilled in the art after having the benefit of this description of the inventions.

What is claimed is:

1. A wafer cleaning method, comprising:
evaporating liquid IPA into IPA vapor in an isopropyl alcohol (IPA) evaporation system of a wafer processing system;
injecting the IPA vapor into a process chamber of the wafer processing system;
condensing the IPA vapor into distilled high purity liquid IPA; and
rinsing a top surface of a semiconductor wafer in the process chamber using the distilled high purity liquid IPA.

2. The wafer cleaning method of claim 1, wherein the condensing includes cooling a back surface of the semiconductor wafer.

3. The wafer cleaning method of claim 1, further comprising:
rinsing the top surface of the semiconductor wafer using deionized water while injecting the IPA vapor into the process chamber.

4. The wafer cleaning method of claim 1, further comprising:
displacing the distilled high purity liquid IPA using a nitrogen gas to dry the semiconductor wafer.

5. The wafer cleaning method of claim 1, further comprising:
filtering, by a gas filter of the wafer processing system, the IPA vapor before injecting the IPA vapor into the process chamber.

6. The wafer cleaning method of claim 1, further comprising:
filtering, by an IPA filter of the wafer processing system, the liquid IPA that is left in the IPA evaporation system after evaporating the liquid IPA.

7. The wafer cleaning method of claim 6, further comprising:
pumping, by an IPA pump of the wafer processing system, the filtered liquid IPA into the IPA evaporation system.

8. The wafer cleaning method of claim 1, further comprising:
heating walls of the process chamber while injecting the IPA vapor into the process chamber.

9. The wafer cleaning method of claim 1, further comprising:
generating a gas curtain flow for walls of the process chamber while injecting the IPA vapor into the process chamber.

10. The wafer cleaning method of claim 1, further comprising:
injecting a heated gas supply into the process chamber to heat the process chamber while injecting the IPA vapor into the process chamber.

11. A wafer processing system, comprising:
an isopropyl alcohol (IPA) evaporation system configured to evaporate liquid IPA into IPA vapor; and
a process chamber configured to
inject the IPA vapor into the process chamber,
condense the IPA vapor into distilled high purity liquid IPA, and
rinse a top surface of a semiconductor wafer in the process chamber using the distilled high purity liquid IPA.

12. The wafer processing system of claim 11, wherein the process chamber is configured to cool a back surface of the semiconductor wafer.

13. The wafer processing system of claim 11, wherein the process chamber is configured to rinse the top surface of the semiconductor wafer using deionized water while injecting the IPA vapor into the process chamber.

14. The wafer processing system of claim 11, wherein the process chamber is configured to displace the distilled high purity liquid IPA using a nitrogen gas to dry the semiconductor wafer.

15. The wafer processing system of claim 11, further comprising:
a gas filter configured to filter the IPA vapor before the IPA vapor is injected into the process chamber.

16. The wafer processing system of claim 11, further comprising:
an IPA filter configured to filter the liquid IPA that is left in the IPA evaporation system after the liquid IPA is evaporated into the IPA vapor.

17. The wafer processing system of claim 16, further comprising:
an IPA pump configured to pump the filtered liquid IPA into the IPA evaporation system.

18. The wafer processing system of claim 11, wherein the process chamber is configured to heat walls of the process chamber while injecting the IPA vapor into the process chamber.

19. The wafer processing system of claim 11, wherein the process chamber is configured to generate a gas curtain flow for walls of the process chamber while injecting the IPA vapor into the process chamber.

20. The wafer processing system of claim 11, wherein the process chamber is configured to inject a heated gas supply into the process chamber to heat the process chamber while injecting the IPA vapor into the process chamber.
